(19) United States
(12) Patent Application Publication
(10) Pub. No.: US 2016/0126421 A1
(43) Pub. Date: May 5, 2016

(54) COMPOSITE ELECTRODE, ARRAY SUBSTRATE AND DISPLAY DEVICE

(71) Applicants: BOE TECHNOLOGY GROUP CO., LTD., Beijing (CN); BEIJING BOE OPTOELECTRONICS TECHNOLOGY CO., Beijing (CN)

(72) Inventors: Jiuxia Yang, Beijing (CN); Feng Bai, Beijing (CN); Jiantao Liu, Beijing (CN)

(21) Appl. No.: 14/742,602

(22) Filed: Jun. 17, 2015

(30) Foreign Application Priority Data
Oct. 30, 2014 (CN) 201410601174.3

(51) Int. Cl. H01L 33/40; H01L 27/12

(52) U.S. Cl. CPC H01L 33/40; H01L 27/1214

(57) ABSTRACT

A composite electrode comprises at least one graphene layer and at least one doping layer, and two adjacent layers are not both the doping layer; wherein the doping layer is an aluminum chloride layer or a zinc iodide layer. It is used for manufacture of a display device.

### RELATED APPLICATIONS

The present disclosure claims the benefit of Chinese Patent Application No. 201410601174.3, filed on Oct. 30, 2014, the entire disclosure of which is incorporated herein by reference.

### FIELD OF THE INVENTION

The present disclosure relates to the field of display technology, particularly to a composite electrode and preparation method thereof, an array substrate and a display device.

### BACKGROUND OF THE INVENTION

The flexible display device has become a generation of new horizons due to its characteristics of light and thin, low power consumption, and flexibility. The conventional display device generally uses a transparent metal oxide conductive material such as indium tin oxide (ITO) or indium zinc oxide (IZO) as the electrode material, however, the mechanical performance of these materials themselves decides that they cannot have good flexibility.

With respect to the flexible display device, the prior art has proposed using a graphene film to replace the above transparent metal oxide electrode as the pixel electrode in the flexible display device, although the graphene film can meet the requirement on flexibility of the display device, its square resistance is relatively high, which can reach 120Ω/□ above, hence, it cannot meet the requirement on low resistance value of the pixel electrode.

### SUMMARY OF THE DISCLOSURE

The embodiment of the present disclosure provides a composite electrode and preparation method thereof, an array substrate and a display device, which can improve the transmission rate of the current carrier of the electrode, thereby reducing square resistance of the electrode.

In order to achieve the above object, the embodiment of the present disclosure adopts the following technical solutions:

On the one hand, a composite electrode is provided, comprising at least one graphene layer and at least one doping layer, and two adjacent layers are not both the doping layer; wherein the doping layer is an aluminum chloride layer or a zinc iodide layer.

Preferably, the amount of the graphene layer is 2-5.

Optionally, a surface of one side of the composite electrode comprises one or more continuously arranged graphene layers.

Further optionally, a surface of the other side of the composite electrode is the doping layer.

Optionally, the graphene layer is attached to the surface of the doping layer through conductive adhesive.

In an embodiment of the composite electrode, wherein the doping layer is formed on the substrate, and the graphene layer is formed on the doping layer.

Optionally, the composite electrode further comprises one or more continuous graphene layers formed above the graphene layer.

Optionally, wherein all the doping layers and all the graphene layers on the substrate have electrode patterns formed through one patterning process.

Optionally, wherein the graphene layer is attached to the surface of the doping layer through conductive adhesive, the doping layer is formed through evaporation process, the specific condition of the evaporation process is: the vacuum degree in the evaporation cavity is 10⁻⁵ Torr, the evaporation temperature is 180° C.

In another embodiment of the composite electrode, wherein the graphene layer is formed on the substrate, and the doping layer is formed on the graphene layer.

Optionally, the composite electrode further comprises one or more continuous graphene layers formed above the doping layer.

Optionally, wherein all the doping layers and all the graphene layers on the substrate have electrode patterns formed through one patterning process.

Optionally, wherein the graphene layer is attached to the surface of the doping layer through conductive adhesive, the doping layer is formed through evaporation process, the specific condition of the evaporation process is: the vacuum degree in the evaporation cavity is 10⁻⁵ Torr, the evaporation temperature is 180° C.

An array substrate is further provided, comprising a substrate, a thin film transistor located on the substrate, and a pixel electrode electrically connected with a drain of the thin film transistor; characterized in that the pixel electrode adopts a composite electrode stated above.

Optionally, the array substrate further comprises a common electrode; wherein the common electrode adopts a composite electrode stated above.

A display device is further provided, comprising an array substrate stated above.

On the other hand, a method for preparing a composite electrode is provided, the method comprising: forming at least one graphene layer and at least one doping layer, and two adjacent layers are not both the doping layer; wherein the doping layer is an aluminum chloride layer or a zinc iodide layer.

Preferably, the amount of the graphene layer is 2-5.

Optionally, the step of forming at least one graphene layer and at least one doping layer specifically comprises: forming one doping layer on the substrate, and forming one graphene layer on the substrate formed with the doping layer; or, forming one graphene layer on the substrate, and forming at least one doping layer on the substrate formed with the graphene layer; forming one or more continuous graphene layers above the substrate formed with the doping layer and the graphene layer; enabling all the graphene layers and all the doping layers on the substrate to form electrode patterns through one patterning process.

Further optionally, the step of enabling all the graphene layers and all the doping layers on the substrate to form electrode patterns through one patterning process comprises specifically: coating photoresist on the surface of the most upper graphene layer; exposing and developing the substrate formed with the photoresist using a mask plate, so as to form photoresist reservation portions and photoresist removal portions; wherein the photoresist reservation portions correspond to regions in which the electrode patterns are formed, and the photoresist removal portions correspond to others regions; removing the graphene layers and the doping layers to which the photoresist removal portions correspond using etching process; removing the photoresist of the photoresist reservation portions using stripping process.

Optionally, the graphene layer is attached through conductive adhesive; the doping layer is formed through evaporation process; wherein the specific condition of the evaporation process is: the vacuum degree in the evaporation cavity is 10⁻⁵ Torr, the evaporation temperature is 180° C.

The embodiment of the present disclosure provides a composite electrode and preparation method thereof, an array substrate and a display device, the composite electrode comprising at least one graphene layer and at least one doping layer, and two adjacent layers are not both the doping layer; wherein the doping layer is an aluminum chloride layer or a zinc iodide layer.

On the basis of this, by arranging the composite electrode as a multilayer of graphene doped structure, and taking the aluminum chloride layer or the zinc iodide as the doping material, a new bond structure can be formed between the graphene layer and the doping layer, so as to enable the doped composite electrode to obtain a relatively high transmission rate of the current carrier, thereby reducing square resistance of the composite electrode.

### BRIEF DESCRIPTION OF DRAWINGS

In order to explain the technical solutions in the embodiments of the present disclosure or the prior art more clearly, the drawings to be used in the description of the embodiments or the prior art will be introduced briefly in the following, apparently, the drawings described below are only some embodiments of the present disclosure, the ordinary skilled person in the art, on the premise of not paying any creative work, can also obtain other drawings from these drawings.

FIG. 1 is a structural schematic view I of a composite electrode provided by an embodiment of the present disclosure;

FIG. 2 is a structural schematic view II of a composite electrode provided by an embodiment of the present disclosure;

FIG. 3 is a structural schematic view III of a composite electrode provided by an embodiment of the present disclosure;

FIG. 4 is a structural schematic view I of an array substrate provided by an embodiment of the present disclosure;

FIG. 5 is a structural schematic view II of an array substrate provided by an embodiment of the present disclosure;

FIG. 6 is a structural schematic view III of an array substrate provided by an embodiment of the present disclosure;

FIG. 7 is a flow chart of a preparation method of a composite electrode provided by an embodiment of the present disclosure;

FIG. 8 is a flow chart of a preparation method of an array substrate provided by an embodiment of the present disclosure;

FIG. 9 is a flow chart of a preparation method of a pixel electrode provided by an embodiment of the present disclosure;

### REFERENCE SIGNS

10—composite electrode; 101—graphene layer; 102—doping layer; 20—substrate; 30—thin film transistor; 40—pizel electrode; 50—common electrode; 60—passivation layer.

### DETAILED DESCRIPTION OF THE INVENTION

Next, the technical solutions in the embodiments of the present disclosure will be described clearly and completely in combination with the drawings in the embodiments of the present disclosure. Apparently, the embodiments described are only a part rather than all of the embodiments of the present disclosure. All other embodiments obtained by the ordinary skilled person in the art from the embodiments in the present disclosure, on the premise of not paying any creative work, belong to the protection scope of the present disclosure.

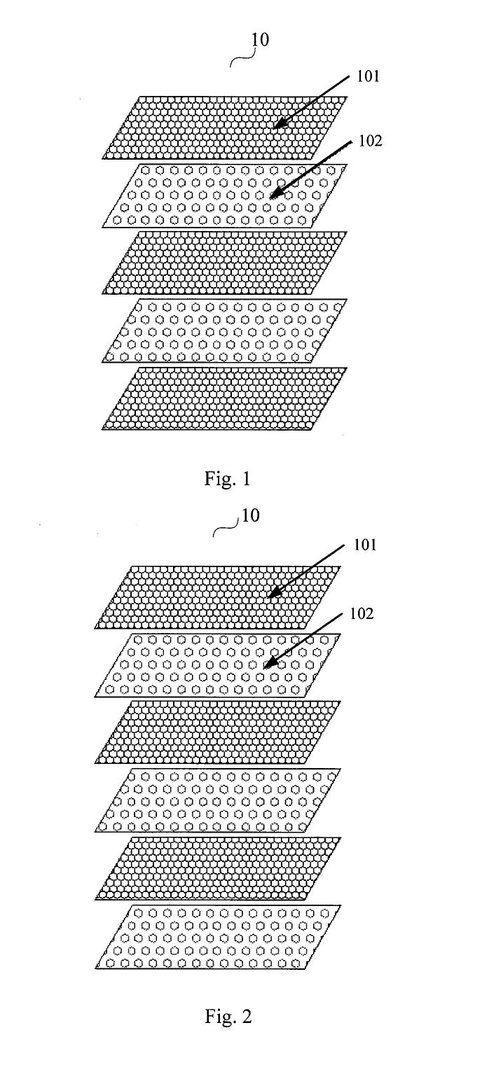

The embodiment of the present invention provides a composite electrode 10, as shown in FIG. 1 to FIG. 3, comprising at least one graphene layer 101 and at least one doping layer 102, and two adjacent layers are not both the doping layer 102; wherein the doping layer 102 is an aluminum chloride layer or a zinc iodide layer.

It should be noted that firstly, the graphene is a sheet structure material constituted by a single layer of carbon atoms, the carbon atoms therein compose a hexagonal honeycomb like lattice structure in sp2 hybrid orbital. In the embodiment of the present disclosure, the graphene layer 101 refers to a graphene film constituted by multilayer graphene.

Secondly, the graphene layer 101 and the doping layer 102 may be arranged in various ways, as long as it can be ensured that two adjacent layers are not both the doping layer 102, that is, the doping layer 102 would not be arranged continuously, there are no other specific definitions.

Exemplarily, the graphene layer 101 and the doping layer 102 may be arranged alternately; or, the doping layer 102 may be arranged between two adjacent graphene layers 101, and the doping layer 102 is not arranged between any two adjacent graphene layers 101; or the doping layer 102 may be arranged at the outermost side of the graphene layer 101.

On the basis of this, in the even that the composite electrode 10 comprises multiple graphene layers 101 more than three layers, the aluminum chloride layer or the zinc iodide layer can be doped between the multiple graphene layers 101 simultaneously; that is to say, the aluminum chloride layer can be doped between the first graphene layers and the second graphene layer, and the zinc iodide layer can be doped between the second graphene layer and the third graphene layer, and so on.

However, in consideration of the complexity of the preparation process, the embodiment of the present disclosure preferably only dopes one material, i.e., the aluminum chloride or the zinc iodide, in the composite electrode 10.

Thirdly, the embodiment of the present disclosure does not define the actual amount of the graphene layer 101, however, since the composite electrode 10 is a transparent electrode, it is mainly applied the display field, hence, the amount of the graphene layer 101 in the composite electrode 10 should be designed based on the transmittance and thickness of the electrode.

The embodiment of the present disclosure a composite electrode 10, comprising at least one graphene layer 101 and at least one doping layer 102, and two adjacent layers are not both the doping layer 102; wherein the doping layer 102 is an aluminum chloride layer or a zinc iodide layer.

On the basis of this, by arranging the composite electrode 10 as a multilayer of graphene doped structure, and taking the aluminum chloride layer or the zinc iodide as the doping material, a new bond structure can be formed between the graphene layer 101 and the doping layer 102, so as to enable the doped composite electrode 10 to obtain a relatively high transmission rate of the current carrier, thereby reducing square resistance of the composite electrode 10.

Based on the above description, the amount of the graphene layer 101 is preferably 2-5.

Wherein, the aluminum chloride layer or the zinc iodide layer can be doped between any two adjacent graphene layers 101.

In this way, by controlling the amount of the graphene layer 101 within the above arrange, not only the transmission rate of the carrier current of the composite electrode 10 can be increased effectively, thereby reducing the square resistance thereof, but also a relatively high transmittance can be ensured simultaneously, so as to enable the composite electrode 10 to be applied in the display field very well.

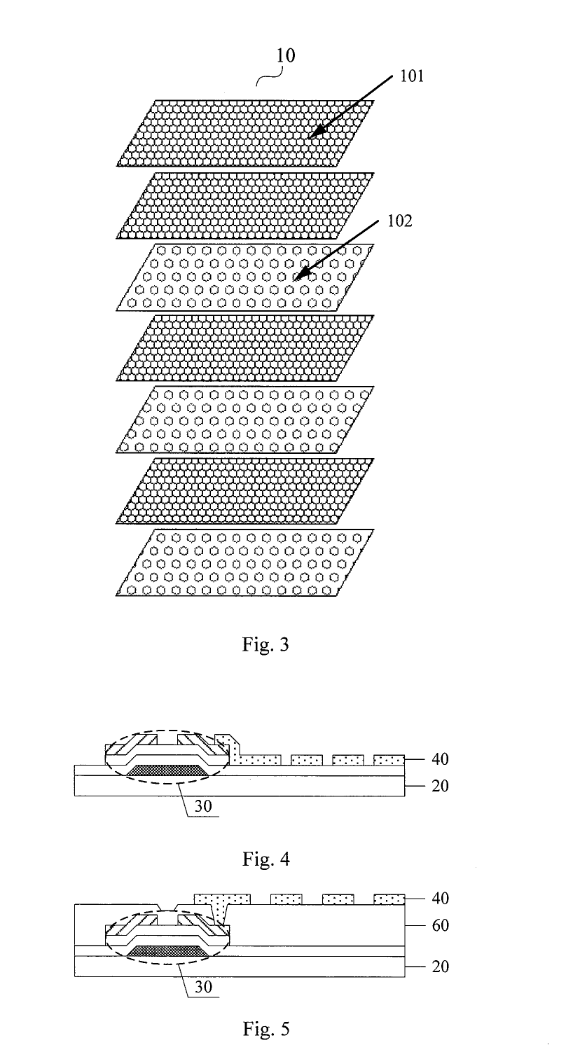

Optionally, as shown in FIG. 3, the surface of one side of the composite electrode 10 may comprise one or more continuously arranged graphene layers 101.

Here, by arranging one or more graphene layers 101 on the surface of one side of the composite electrode 10, the electrical properties of the pixel electrode 40 can be further improved.

On the basis of this, the surface of the other side of the composite electrode 10 may be arranged as the doping layer 102.

Certainly, both of the two sides of the composite electrode 10 here may also be arranged as graphene layers 101 or doping layers 102, as long as there are no continuously arranged doping layers 102.

Based on the above, optionally, the graphene layer 101 may be attached to the surface of the doping layer 102 through conductive adhesive.

It should be noted here that the embodiment of the present disclosure only defines the combination mode of the graphene layer 101 with the doping layer 102, however, the combination mode of the doping layer 102 with the graphene layer 101 is not defined; that is to say, the graphene layer 101 can be attached to the surface of the doping layer 102 through conductive adhesive, while the doping layer 102 can be formed on the surface of the graphene layer 101 through other modes e.g. evaporation.

The embodiment of the present disclosure further provides an array substrate, as shown in FIG. 4 and FIG. 5, comprising a substrate 20, a thin film transistor 30 located on the substrate 20, and a pixel electrode 40 electrically connected with the drain of the thin film transistor 30; wherein the pixel electrode 40 may adopt the above composite electrode 10.

Here, the thin film transistor 30 may comprise a gate, a gate insulating layer, a semiconductor active layer, a source and a drain. Wherein, the semiconductor active layer may be an amorphous silicon semiconductor active layer or a metal oxide semiconductor active layer.

On the basis of this, the thin film transistor 30 may be a bottom gate type or a top gate type; according to the different types of the thin film transistor 30, the electrical connection of the pixel electrode 40 with the drain will also be different. Here it should be noted that the drawings only take the example of the bottom gate type thin film transistor to explain the structure of the array substrate, however, the protection scope of the present invention is not limited to this.

Exemplarily, in the event that the thin film transistor 30 is a bottom gate type thin film transistor, as shown in FIG. 4, the pixel electrode 40 may be electrically connected with the drain of the thin film transistor 30 through bridge connection; or as shown in FIG. 5, a passivation layer 60 may also be arranged between the thin film transistor 30 and the pixel electrode; wherein the pixel electrode 40 may be electrically connected with the drain of the thin film transistor 30 through the via hole in the passivation layer 60.

From the above description it can be seen that the composite electrode has a relatively high transmission rate of carrier current and a relatively low square resistance, as well as good flexibility, by taking the composite electrode 10 as the pixel electrode 40, not only a good electrical property can be obtained, but also the requirement of flexible display can be met very well simultaneously.

On the basis of this, the surface of one side of the pixel electrode 40 away from the substrate 20 may comprise one or more continuously arranged graphene layers 101; the surface of one side of the pixel electrode close to the substrate 20 may be arranged as the doping layer 102.

Wherein, since the graphene layer 101 and the doping layer 102 are used for forming the pixel electrode 40, while the pixel electrode 40 has a certain shape, therefore, it is required to pattern the graphene layer 101 and the doping layer 102.

Specifically, the graphene layer 101 may be attached to the surface of the doping layer 102 directly, then the graphene layer 101 and the doping layer 102 are enabled to form the desired patterns through patterning process; or the graphene layer 101 and the doping layer 102 are enabled to form the desired patterns through patterning process firstly, then the patterned graphene layer 101 is attached to the corresponding position of the surface of the doping layer 102.

The embodiment of the present disclosure does not define the filming and patterning sequence of the composite electrode 10 specifically, however, in consideration of the simplification of the preparation process, here it is preferred to form the desired electrode patterns only through one patterning process after all the films are formed.

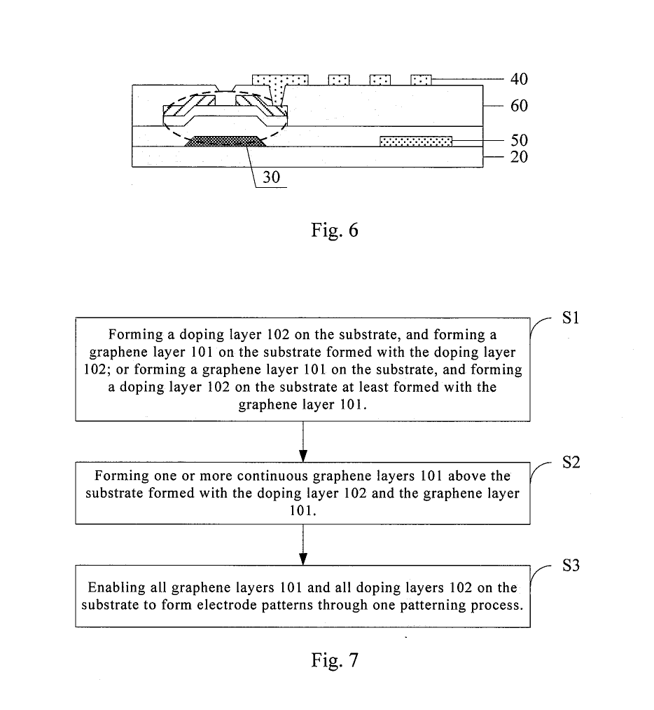

Optionally, as shown in FIG. 6, the array substrate may further comprise a common electrode 50; wherein the common electrode may adopt the above composite electrode 10.

Thus, the array substrate may comprise both the pixel electrode 40 and the common electrode 50

On the basis of this, the pixel electrode 40 and the common electrode 50 may be arranged in the same layer, thereby forming an array substrate applied in an in-plane switching (IPS) type display device.

Or, the pixel electrode 40 and the common electrode 50 may be arranged in different layers, and the electrode located above is a strip electrode, the electrode located below is a strip or a plate electrode, thereby forming an array substrate applied in an advanced-super dimensional switching (ADS) type display device.

Wherein, the ADS type display device may form a multidimensional electric field through the electric field generated at the edge of the slit electrode and the electric field generated between the slit electrode layer and the plate electrode layer within the same plane, so as to enable liquid crystal molecules of all orientations between the slit electrodes in the liquid crystal box and directly above the electrode to rotate, thereby improving working efficiency of the liquid crystals and increasing tansmittance efficiency. The advanced-super dimensional switching technology can improve image quality of the display panel, and has the advantages of high resolution, high transmittance, low power consumption, wide viewing angle, high opening rate, low chromatic aberration and no squeezing water ripple.

The embodiment of the present disclosure further provides a display device comprising the above array substrate.

The display device may be a liquid crystal display (LCD) or an organic light emitting diode (OLED).

The embodiment of the present disclosure provides a preparation method of a composite electrode 10, the method comprising: forming at least one graphene layer 101 and at least one doping layer 102, and two adjacent layers are not both the doping layer 102; wherein the doping layer 102 is an aluminum chloride layer or a zinc iodide layer.

It should be noted here that the graphene layer 101 and the doping layer 102 may be formed in various orders specifically, for example, the graphene layer 101 and the doping layer 102 may be formed alternately in turn; or, the doping layer 102 may be formed between certain two adjacent graphene layers 101 in the multiple graphene layers 101, or the doping layer 102 may be formed at the outermost side of the graphene layer 101, as long as there are not two continuously formed doping layers 102.

On the basis of this, the aluminum chloride layer and the zinc iodide layer can be doped between the multiple graphene layers 101 simultaneously; that is to say, the aluminum chloride layer can be doped between the first graphene layers and the second graphene layer, and the zinc iodide layer can be doped between the second graphene layer and the third graphene layer, and so on. In consideration of complexity of the preparation process, the embodiment of the present disclosure preferably only forms one doping material, i.e., the aluminum chloride or the zinc iodide, in the composite electrode 10.

On the basis of this, by forming the above multilayer of graphene doped structure, a new bond structure can be formed between the graphene layer 101 and the doping layer 102, so as to enable the doped composite electrode 10 to obtain a relatively high transmission rate of carrier current, thereby reducing square resistance of the composite electrode 10.

Preferably, the amount of the graphene layer is 2 to 5; by controlling the amount of the graphene layer 101 within this range, not only the transmission rate of the carrier current of the composite electrode 10 can be increased effectively, thereby reducing the square resistance thereof, but also a relatively high transmittance can be ensured simultaneously, so as to enable the composite electrode 10 to be applied in the display field very well.

Optionally, as shown in FIG. 7, the step of forming at least one graphene layer 101 and at least one doping layer 102 specifically comprises:

S1. Forming one doping layer 102 on the substrate, and forming one graphene layer 101 on the substrate formed with the doping layer 102; or, forming one graphene layer 101 on the substrate, and forming at least one doping layer 102 on the substrate formed with the graphene layer 101;

Wherein, the graphene layer 101 can be attached through conductive adhesive; the doping layer 102 can be formed through evaporation process; wherein the specific condition of the evaporation process is: the vacuum degree in the evaporation cavity is 10⁻⁵ Torr, the evaporation temperature is 180° C.

Here, the film firstly formed on the substrate may be the graphene layer 101 or the doping layer 102. Wherein, in the event that the doping layer 102 is formed firstly, it is required to form the graphene layer 101 on the doping layer 102 directly; in the event that the graphene layer 101 is formed firstly, the graphene layer 101 or the doping layer 102 may be formed on the graphene layer 101.

S2. Forming one or more continuous graphene layers 101 above the substrate formed with the doping layer 102 and the graphene layer 101.

It should be noted that other graphene layers 101 and/or doping layers 102 may be formed possibly between step S1 and step S2; in such a case, step S2 would be further forming at least one graphene layer 101 on the substrate formed with other graphene layers 101 and/or doping layers 102.

S3. Enabling all graphene layers 101 and all doping layers 102 on the substrate to form electrode patterns through one patterning process.

Wherein, the step S3 may comprise specifically:

S301. Coating photoresist on the surface of the utmost upper graphene layer 101.

S302. Exposing and developing the substrate formed with the photoresist using a mask plate, so as to form photoresist reservation portions and photoresist removal portions; wherein the photoresist reservation portions correspond to regions in which the electrode patterns are formed, and the photoresist removal portions correspond to others regions.

S303. Removing the graphene layers 101 and the doping layers 102 to which the photoresist removal portions correspond using etching process.

S304. Removing the photoresist of the photoresist reservation portions using stripping process.

Based on the above steps S1-S3, the preparation of the composite electrode 10 can be accomplished only through one patterning process.

It should be noted that the graphene layers 101 and the doping layers 102 may form the desired patterns only through one patterning process, however, the desired patterns may also be formed by performing patterning with respect to each layer respectively, which will not be defined here specifically.

In addition, the graphene layer 101 may be attached to the surface of the doping layer 102 firstly, and then patterned to form the desired patterns, or the patterned graphene layer may be attached to the surface of the doping layer 102.

Next, the preparation process of the array substrate will be explained in detail by taking the example that the composite electrode serves as the pixel electrode 40; wherein, as shown in FIG. 3, the pixel electrode 40 (i.e., the composite electrode 10) comprises four graphene layers 101 and three doping layers 102, and the doping layers 102 are aluminum chloride (AlCl₃) layers.

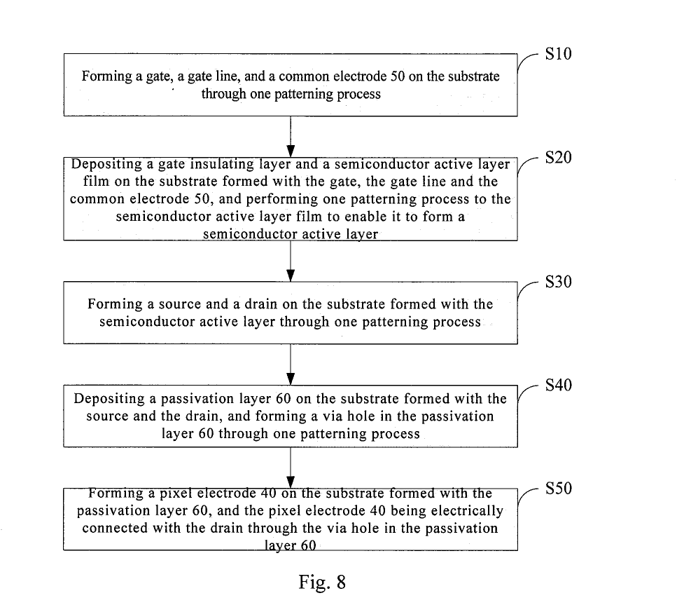

Specifically, as shown in FIG. 8, the method may comprise:

S10. Forming a gate, a gate line, and a common electrode 50 on the substrate through one patterning process.

Wherein, the substrate may be a flexible substrate formed on the glass substrate; the flexible substrate cannot be stripped from the glass substrate before the preparation of the array substrate is accomplished.

S20. Depositing a gate insulating layer and a semiconductor active layer film on the substrate formed with the gate, the gate line and the common electrode 50, and performing one patterning process to the semiconductor active layer film to enable it to form a semiconductor active layer.

Wherein, the material of the gate insulating layer generally may adopt any one of the insulating materials such as silicon nitride, silicon oxide, silicon oxynitride, and aluminum oxide; the semiconductor active layer may be a metal oxide semiconductor active layer, it may specifically adopt any one of the transparent metal oxide semiconductor materials such as indium gallium zinc oxide (IGZO) or indium tin zinc oxide (ITZO).

S30. Forming a source and a drain on the substrate formed with a semiconductor active layer through one patterning process.

Certainly, a data line may also be formed at the same time of forming the source and the drain.

S40. Depositing a passivation layer 60 on the substrate formed with the source and the drain, and forming a via hole in the passivation layer 60 through one patterning process.

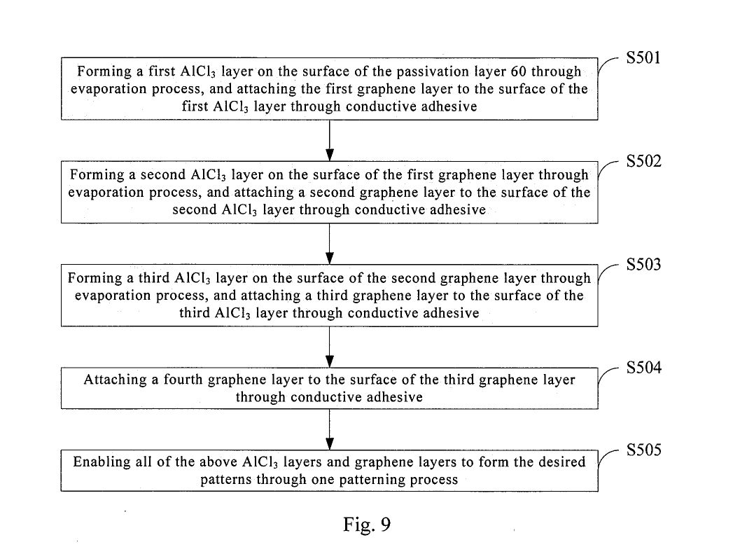

S50. Forming a pixel electrode 40 on the substrate formed with the passivation layer 60, and the pixel electrode 40 being electrically connected with the drain through the via hole in the passivation layer 60.

Wherein, as shown in FIG. 9, the specific process of forming the pixel electrode 40 is as follows:

S501. Forming a first AlCl₃ layer on the surface of the passivation layer 60 through evaporation process, and attaching the first graphene layer to the surface of the first AlCl₃ layer through conductive adhesive.

Wherein, the evaporation process of the AlCl₃ layer is specifically: the vacuum degree in the evaporation cavity is 10⁻⁵ Torr, the evaporation temperature is 180° C.

S502. Forming a second AlCl₃ layer on the surface of the first graphene layer through evaporation process, and attaching a second graphene layer to the surface of the second AlCl₃ layer through conductive adhesive.

S503. Forming a third AlCl₃ layer on the surface of the second graphene layer through evaporation process, and attaching a third graphene layer to the surface of the third AlCl₃ layer through conductive adhesive.

S504. Attaching a fourth graphene layer to the surface of the third graphene layer through conductive adhesive.

S505. Enabling all of the above AlCl₃ layers and graphene layers to form the desired patterns through one patterning process.

Specifically, photoresist is coated on the surface of the fourth graphene layer, and the substrate formed with the photoresist is exposed and developed through a mask plate, so as to form photoresist reservation portions and photoresist removal portions; wherein the photoresist reservation portions correspond to the regions where the electrode patterns are formed, the photoresist removal portions correspond to other regions; then the AlCl₃ layers and the graphene layers to which the photoresist removal portions correspond are removed through etching process, and finally, the photoresist of the photoresist reservation portions are stripped off, thereby enabling the AlCl₃ layers and graphene layers to form the desired electrode patterns.

In this way, the preparation of the pixel electrode 40 can be accomplished; wherein the pixel electrode 40 totally comprises four graphene layers and three AlCl₃ layers.

Based on the above steps S1-S5, the preparation of the array substrate as shown in FIG. 6 can be accomplished. The array substrate can be applied in an advanced-super dimensional switching (ADS) type display device. On the basis of this, since the composite electrode 10 has a relatively high transmission rate of carrier current and a relatively low square resistance, using the composite electrode 10 as the pixel electrode 40 can obtain good electrical properties, and can also meet the requirement of flexible display simultaneously.

It should be noted here that the pixel electrode 40 provided by the embodiment of the present disclosure can also be applied in a twisted nematic (TN) type display device or an IPS type display device.

What are stated above are only specific implementing modes of the present disclosure, however, the protection scope of the present disclosure is not limited to this, any modifications or replacements that the skilled person familiar with the present technical field can easily think of within the technical scope disclosed by the present disclosure should be covered within the protection scope of the present disclosure. Therefore, the protection scope of the present disclosure should be based on the protection scopes of the claims.

1. A composite electrode, comprising at least one graphene layer and at least one doping layer, and two adjacent layers are not both the doping layer;
wherein the doping layer is an aluminum chloride layer or a zinc iodide layer.

2. The composite electrode according to claim 1, wherein the amount of the graphene layer is 2-5.

3. The composite electrode according to claim 1, wherein a surface of one side of the composite electrode comprises one or more continuously arranged graphene layers.

4. The composite electrode according to claim 3, wherein a surface of the other side of the composite electrode is the doping layer.

5. The composite electrode according to claim 1, wherein the graphene layer is attached to the surface of the doping layer through conductive adhesive.

6. The composite electrode according to claim 1, wherein the doping layer is formed on the substrate, and the graphene layer is formed on the doping layer.

7. The composite electrode according to claim 6, further comprising one or more continuous graphene layers formed above the graphene layer.

8. The composite electrode according to claim 7, wherein all the doping layers and all the graphene layers on the substrate have electrode patterns formed through one patterning process.

9. The composite electrode according to claim 8, wherein the graphene layer is attached to the surface of the doping layer through conductive adhesive, the doping layer is formed through evaporation process, the specific condition of the evaporation process is: vacuum degree in the evaporation cavity is 10⁻⁵ Torr, evaporation temperature is 180° C.

10. The composite electrode according to claim 1, wherein the graphene layer is formed on the substrate, and the doping layer is formed on the graphene layer.

11. The composite electrode according to claim 10, further comprising one or more continuous graphene layers formed above the doping layer.

12. The composite electrode according to claim 11, wherein all the doping layers and all the graphene layers on the substrate have electrode patterns formed through one patterning process.

13. The composite electrode according to claim 12, wherein the graphene layer is attached to the surface of the doping layer through conductive adhesive, the doping layer is formed through evaporation process, the specific condition of the evaporation process is: vacuum degree in the evaporation cavity is 10⁻⁵ Torr, evaporation temperature is 180° C.

14. An array substrate, comprising a substrate, a thin film transistor located on the substrate, and a pixel electrode electrically connected with a drain of the thin film transistor; wherein the pixel electrode adopts a composite electrode according to claim 1.

15. The array substrate according to claim 14, wherein the array substrate further comprises a common electrode;
wherein the common electrode adopts a composite electrode according to claim 1.

16. A display device, wherein it comprises an array substrate according to claim 14.
